(19) United States
(12) Patent Application Publication
(10) Pub. No.: US 2019/0242538 A1
(43) Pub. Date: Aug. 8, 2019

(54) FLEXIBLE LIGHT BELT APPARATUS

(71) Applicant: XIAMEN ECO LIGHTING CO. LTD., XIAMEN (CN)

(72) Inventors: Maojin Zeng, XIAMEN (CN); Yongzhe Dong, XIAMEN (CN); Wanfeng Deng, XIAMEN (CN)

(21) Appl. No.: 15/898,012

(22) Filed: Feb. 15, 2018

(30) Foreign Application Priority Data
Feb. 7, 2018 (CN) 201820222332.8

(51) Int. Cl. F21S 4/22; H05K 1/02; H05K 1/18; F21V 7/00; F21V 7/04; F21V 29/505; F21V 31/04; F21V 3/02

(52) U.S. Cl. CPC F21S 4/22; H05K 1/028; H05K 1/181; F21V 7/005; F21Y 2115/10; F21V 29/505; F21V 31/04; F21V 3/02; H05K 2201/10106; F21V 7/04

(57) ABSTRACT

A light belt apparatus has a base belt, a flexible circuit board, LED modules and an input terminal. The base belt is made of plastic material and has an elongated flexible body. The elongated flexible body has an elongated groove with a first side and a second side. The first side and the second side is opposite to each other. The flexible circuit board is attached to the first side of the base belt. The LED modules emits an emitted light to the second side of the base belt, the second side of the base belt having a reflective curve surface reflecting the emitted light to exit the groove. The input terminal supplies electricity to the flexible circuit board.

### FIELD OF INVENTION

The present invention is related to a light belt apparatus and more particularly related to a LED light belt apparatus.

### BACKGROUND

Artificial light is critical to human life today. Not only serving as luminous source in various building or outdoor environment, various light devices make human life better and better.

Some lights may be designed for decorative purpose while some others may be designed for emphasizing portability. There are also many factors to consider, e.g. heat dissipation, luminous efficacy, robustness of products, life span.

It is important to design useful and reliable light components so that light designers may rely on such light components to build more interesting and helpful products.

### SUMMARY OF THE INVENTION

According to an embodiment of the present invention, a light belt apparatus includes a base belt, a flexible circuit board, multiple LED modules, and an input terminal.

The base belt is made of plastic material and has an elongated flexible body. The elongated flexible body has an elongated groove with a first side and a second side. The first side and the second side are opposite to each other.

The flexible circuit board is attached to the first side of the base belt.

The LED modules are mounted on the flexible circuit board. The LED modules emit an emitted light to the second side of the base belt. The second side of the base belt has a reflective curve surface reflecting the emitted light to exit the groove.

The input terminal electrically is connected to the flexible circuit board for supplying electricity power to the LED modules to generate the emitted light.

In some embodiments, the LED modules have a series of LED chips arranged in series and a constant current source is provided to the LED chips. In some design, the LED chips are connected in series, in parallel or in any combination so that no further driver circuit is necessary to keep the LED module working.

Each LED module may contain one or more than one LED chips packaged with various technologies, including but not limited to SMD (Surface Mounted Device), COB (Chip on Board), Flip Chip, CSP (Chip Scale Package).

In some embodiments, the base belt is made of an elongated plastic bar with a trench as the elongated groove. An elongated flexible circuit board mounted with LED chips is attached to a side of the trench. The emitted light from the LED chips are reflected by the side wall of the trench to the outside. Some protective or diffusion layer may be added above the trench.

Please be noted that the inventive concept may also extend to rigid light belt structures.

In some embodiments, the first side of the elongated groove is connected with the second side with a bottom side in the elongated groove. The reflective curve surface is extended from the bottom side to the second side to reflect the emitted light toward the bottom side and the second side to exit the elongated groove.

In some embodiments, the second side has a vertical part and a curve part. The curve part is connected to the bottom side, and the vertical part is substantially parallel to the first side. In other words, there is a curve surface forming in the connection part of the second side and the bottom side of the elongated groove. When light is emitted downwardly to the reflective curve surface, the light is reflected to leave the elongated groove or reflected to other part of the elongated groove and finally leaves the elongated groove.

In some embodiments, the curve part of the second side and the bottom side form a smooth convex curve surface facing to the LED modules. Such convex surface form a concave mirror to reflect light emitted on the concave mirror to a desired direction, e.g. to leave the elongated groove.

In some embodiments, the second side of the elongated groove has a tilt angle with respect to the first side, and the tilt angle is less than 60 degrees. Compared with previous embodiments, where the second side still has a vertical part in parallel to the first side, in these embodiments, the second side is directly a tilt surface for reflecting light outside the elongated groove. The second side may also has a convex curve surface at its bottom, just like the previous embodiments.

In such embodiments, more light is directly reflected and directed outside the elongated groove.

In some embodiments, the reflective curve surface has a reflective layer. In other words, not depending on original material of the base belt, the reflective curve surface has a better reflective effect by adding a reflective layer.

In some embodiments, the reflective layer is made of paint material attached on the second side as the reflective curve surface. For example, a silver or white color paint is applied on the reflective surface.

In some embodiments, the reflective layer is a reflective component attached on the second side of the elongated groove. For example, a reflective paper, a reflective metal sheet, a reflective plastic sheet may be used in the invention.

In some embodiments, the reflective component assists heat dissipation. When light is emitted on the reflective component, there is certain heat to be removed. The reflective component may be further attached to an external heat sink or just dissipate heat to make the light belt more robust with longer life span.

In some embodiments, the light belt apparatus also include a light diffusion layer covering the elongated groove. With the light diffusion layer, the light would not be too aggressive, harming human eyes.

In some embodiments, the light diffusion layer may be mixed with color material for providing a required color.

In some embodiments, the top surface of the light diffusion layer has a curve surface. This may produce lens effect to guide output light as a more helpful pattern in various applications.

In some embodiments, the light belt apparatus may further include a transparent material filled in the elongated groove facing to the first side and the second side. Unlike filling the diffusion layer material directly in the elongated groove, such transparent material may further increase luminous efficacy.

In some embodiments, the LED modules may have multiple LED types, i.e. having different parameters. Different LED modules are distributed on the flexible circuit board in a predetermined order and arrangement for generating a synthesized light effect.

For example, the LED modules may have LED chips with different color temperatures. By mixing LED chips with different color temperature, a mixed color temperature may better meet the requirement of light design.

In some other embodiments, the LED modules may have LED chips with different colors, e.g. to provide better CRI (Color Rendering Index).

In some embodiments, the light belt apparatus may further include a driver circuit for converting electricity from the input terminal to a driving current of the LED modules. With such design, designers do not need to further implement an external driver but to connect the light belt apparatus to a power source.

In some embodiments, the flexible circuit board may have a reflective surface for reflecting light. When the light is reflected from the second side of the elongated groove, the flexible circuit board may further reflect the light to another direction, so as to increase final overall luminous efficacy.

### BRIEF DESCRIPTION OF DRAWINGS

FIG. 1 illustrates a light belt apparatus embodiment.

FIG. 2 is a diagram explaining inner structure of a light belt apparatus embodiment.

FIG. 3 is a diagram explaining inner structure of another light belt apparatus embodiment.

FIG. 4 illustrates another light belt apparatus embodiment.

FIG. 5 is a diagram explaining inner structure of a light belt embodiment.

FIG. 6 is a diagram explaining inner structure of another light belt embodiment.

### DETAILED DESCRIPTION

According to an embodiment of the present invention, a light belt apparatus includes a base belt, a flexible circuit board, multiple LED modules, and an input terminal.

The base belt is made of plastic material and has an elongated flexible body. The elongated flexible body has an elongated groove with a first side and a second side. The first side and the second side are opposite to each other.

The flexible circuit board is attached to the first side of the base belt.

The LED modules are mounted on the flexible circuit board. The LED modules emit an emitted light to the second side of the base belt. The second side of the base belt has a reflective curve surface reflecting the emitted light to exit the groove.

The input terminal electrically is connected to the flexible circuit board for supplying electricity power to the LED modules to generate the emitted light.

In some embodiments, the LED modules have a series of LED chips arranged in series and a constant current source is provided to the LED chips. In some design, the LED chips are connected in series, in parallel or in any combination so that no further driver circuit is necessary to keep the LED module working.

Each LED module may contain one or more than one LED chips packaged with various technologies, including but not limited to SMD (Surface Mounted Device), COB (Chip on Board), Flip Chip, CSP (Chip Scale Package).

In some embodiments, the base belt is made of an elongated plastic bar with a trench as the elongated groove. An elongated flexible circuit board mounted with LED chips is attached to a side of the trench. The emitted light from the LED chips are reflected by the side wall of the trench to the outside. Some protective or diffusion layer may be added above the trench.

Please be noted that the inventive concept may also extend to rigid light belt structures.

In some embodiments, the first side of the elongated groove is connected with the second side with a bottom side in the elongated groove. The reflective curve surface is extended from the bottom side to the second side to reflect the emitted light toward the bottom side and the second side to exit the elongated groove.

In some embodiments, the second side has a vertical part and a curve part. The curve part is connected to the bottom side, and the vertical part is substantially parallel to the first side. In other words, there is a curve surface forming in the connection part of the second side and the bottom side of the elongated groove. When light is emitted downwardly to the reflective curve surface, the light is reflected to leave the elongated groove or reflected to other part of the elongated groove and finally leaves the elongated groove.

In some embodiments, the curve part of the second side and the bottom side form a smooth convex curve surface facing to the LED modules. Such convex surface form a concave mirror to reflect light emitted on the concave mirror to a desired direction, e.g. to leave the elongated groove.

In some embodiments, the second side of the elongated groove has a tilt angle with respect to the first side, and the tilt angle is less than 60 degrees. Compared with previous embodiments, where the second side still has a vertical part in parallel to the first side, in these embodiments, the second side is directly a tilt surface for reflecting light outside the elongated groove. The second side may also has a convex curve surface at its bottom, just like the previous embodiments.

In such embodiments, more light is directly reflected and directed outside the elongated groove.

In some embodiments, the reflective curve surface has a reflective layer. In other words, not depending on original material of the base belt, the reflective curve surface has a better reflective effect by adding a reflective layer.

In some embodiments, the reflective layer is made of paint material attached on the second side as the reflective curve surface. For example, a silver or white color paint is applied on the reflective surface.

In some embodiments, the reflective layer is a reflective component attached on the second side of the elongated groove. For example, a reflective paper, a reflective metal sheet, a reflective plastic sheet may be used in the invention.

In some embodiments, the reflective component assists heat dissipation. When light is emitted on the reflective component, there is certain heat to be removed. The reflective component may be further attached to an external heat sink or just dissipate heat to make the light belt more robust with longer life span.

In some embodiments, the light belt apparatus also include a light diffusion layer covering the elongated groove. With the light diffusion layer, the light would not be too aggressive, harming human eyes.

In some embodiments, the light diffusion layer may be mixed with color material for providing a required color.

In some embodiments, the top surface of the light diffusion layer has a curve surface. This may produce lens effect to guide output light as a more helpful pattern in various applications.

In some embodiments, the light belt apparatus may further include a transparent material filled in the elongated groove facing to the first side and the second side. Unlike filling the diffusion layer material directly in the elongated groove, such transparent material may further increase luminous efficacy.

In some embodiments, the LED modules may have multiple LED types, i.e. having different parameters. Different LED modules are distributed on the flexible circuit board in a predetermined order and arrangement for generating a synthesized light effect.

For example, the LED modules may have LED chips with different color temperatures. By mixing LED chips with different color temperature, a mixed color temperature may better meet the requirement of light design.

In some other embodiments, the LED modules may have LED chips with different colors, e.g. to provide better CRI (Color Rendering Index).

In some embodiments, the light belt apparatus may further include a driver circuit for converting electricity from the input terminal to a driving current of the LED modules. With such design, designers do not need to further implement an external driver but to connect the light belt apparatus to a power source.

In some embodiments, the flexible circuit board may have a reflective surface for reflecting light. When the light is reflected from the second side of the elongated groove, the flexible circuit board may further reflect the light to another direction, so as to increase final overall luminous efficacy.

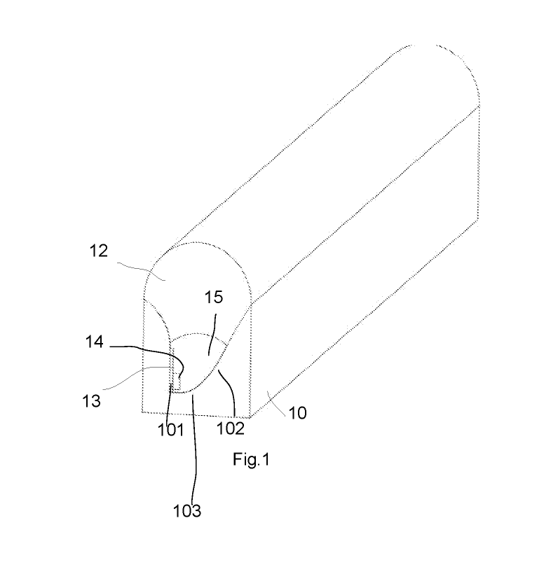

Please refer to FIG. 1, which illustrates a light belt apparatus embodiment.

In FIG. 1, as mentioned above, the light belt apparatus has a base belt 10, a diffusion layer 12, a transparent material 15, a flexible circuit board 13, and a LED module 14.

The LED module 14 is mounted on the flexible circuit board 13. The transparent material 15 is filled in an elongated groove of the base belt 10.

The elongated groove of the base belt 10 has a first side 102, a second side 101. The first side 102 is opposing to the second side 101. There is a bottom side 103 connecting the first side 101 and the second side 102. A reflective curve surface is existed in the second side for reflecting light emitted from the LED module 14.

The diffusion layer 12 covers on the transparent material and may combine with the base belt 10 for creating water proof effect.

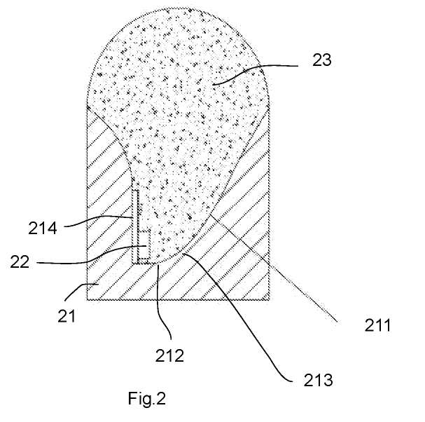

Please refer to FIG. 2, which illustrates an inner structure of a light belt apparatus.

In FIG. 2, there is no transparent material as in FIG. 1. The material of the diffusion layer 23 directly fill in the elongated groove. The LED module emits light to the reflective curve surface 213, which is partly the bottom side 212 of the elongated groove and partly the second side 211. The first side 214 may also be prepared with reflective effect for enhancing luminous efficacy.

It is clear that the second side 211 has a tilt angle with respect to the first side 214. The tilt angle may be 45 degrees, or less than 60 degrees for most cases, to reflect light emitted thereon outside the groove. The diffusion layer 23 helps render output light soft and smooth.

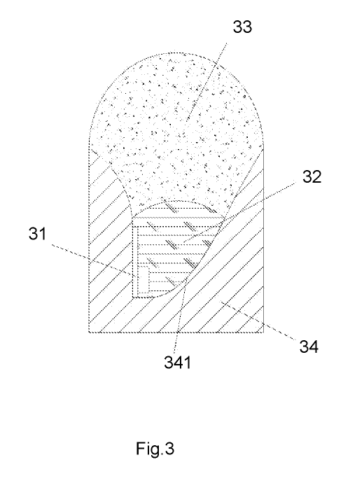

Please refer to FIG. 3, which illustrates an inner structure of a light belt apparatus.

In FIG. 3, there is transparent material filled in an elongated groove of the base belt 34. With the transparent material, light has better luminous efficacy before hitting the reflective curve surface 341. The reflected light is also influenced by the diffusion layer 33 to generate soft luminous effect.

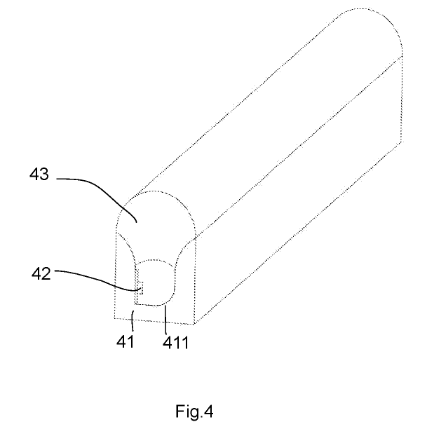

Please refer to FIG. 4, which illustrates another light belt apparatus embodiment.

In FIG. 4, there is still a base belt 41, LED modules 42 and a diffusion layer 43 covering the base belt 41. There is also a reflective curve surface in the elongated groove of the base belt 41, but they have less tilt angle as the embodiment in FIG. 1. The second side is substantially parallel to the first side of the elongated groove, but with a curve part at its bottom connecting to the bottom side of the elongated groove.

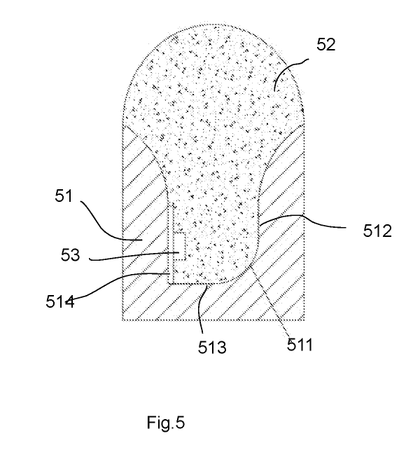

Please refer to FIG. 5, which illustrates a light belt apparatus embodiment.

In FIG. 5, the base belt 51 has a first side 514, a second 512, and a bottom side. The LED module 53 emits light to the second side 512. A reflective curve surface 511 exists between at the bottom of the second side 512 and the bottom side 513. The diffusion layer 52 helps soften the output light effect.

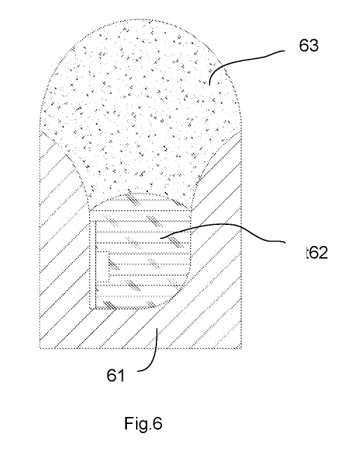

Please refer to FIG. 6, which illustrates another light belt embodiment.

In FIG. 6, the embodiment is similar to the embodiment of FIG. 5. In addition, there is a transparent material 62 filled in the elongated groove of the base belt 61. The transparent material 62 is then covered by the diffusion layer 63 to keep the overall soft light effect while increasing total luminous efficacy.

In addition to the above-described embodiments, various modifications may be made, and as long as it is within the spirit of the same invention, the various designs that can be made by those skilled in the art are belong to the scope of the present invention.

1. A light belt apparatus, comprising:
a base belt made of plastic material and having an elongated flexible body, the elongated flexible body having an elongated groove with a first side and a second side, the first side and the second side being opposite to each other;
a flexible circuit board attached to the first side of the base belt;
a plurality of LED modules mounted on the flexible circuit board, the plurality of LED modules for emitting an emitted light to the second side of the base belt, the second side of the base belt having a reflective curve surface reflecting the emitted light to exit the groove; and
an input terminal electrically connected to the flexible circuit board for supplying electricity power to the LED modules to generate the emitted light.

2. The light belt apparatus of claim 1, wherein the first side is connected with the second side with a bottom side in the elongated groove, and the reflective curve surface is extended from the bottom side to the second side to reflect the emitted light toward the bottom side and the second side to exit the elongated groove.

3. The light belt apparatus of claim 2, wherein the second side has a vertical part and a curve part, the curve part is connected to the bottom side, the vertical part is substantially parallel to the first side.

4. The light belt apparatus of claim 3, wherein the curve part of the second side and the bottom side form a smooth convex curve surface facing to the LED modules.

5. The light belt apparatus of claim 2, wherein the second side has a tilt angle with respect to the first side, and the tilt angle is less than 60 degrees.

6. The light belt apparatus of claim 5, wherein the bottom side and the second side form a smooth convex curve surface facing to the LED modules.

7. The light belt apparatus of claim 6, wherein the second side has a concave surface connected to the smooth convex curve surface.

8. The light belt apparatus of claim 1, wherein the reflective curve surface has a reflective layer.

9. The light belt apparatus of claim 8, wherein the reflective layer is made of paint material attached on the second side as the reflective curve surface.

10. The light belt apparatus of claim 8, wherein the reflective layer is a reflective component attached on the second side of the elongated groove.

11. The light belt apparatus of claim 10, wherein the reflective component assists heat dissipation.

12. The light belt apparatus of claim 1, further comprising a light diffusion layer covering the elongated groove.

13. The light belt apparatus of claim 1, wherein the light diffusion layer is mixed with color material for providing a required color.

14. The light belt apparatus of claim 1, wherein the top surface of the light diffusion layer has a curve surface.

15. The light belt apparatus of claim 1, further comprising a transparent material filled in the elongated groove facing to the first side and the second side.

16. The light belt apparatus of claim 1, wherein the LED modules has a plurality of LED types, distributed on the flexible circuit board for generating a synthesized light effect by the plurality of LED types.

17. The light belt apparatus of claim 1, wherein the plurality of LED types comprise LED chips with different color temperatures.

18. The light belt apparatus of claim 1, wherein the plurality of LED types comprise LED chips with different colors.

19. The light belt apparatus of claim 1, further comprising a driver circuit for converting electricity from the input terminal to a driving current of the LED modules.

20. The light belt apparatus of claim 1, wherein the flexible circuit board has a reflective surface for reflecting light emitted on the reflective surface.
